(19) United States
(12) Patent Application Publication
(10) Pub. No.: US 2022/0130879 A1
(43) Pub. Date: Apr. 28, 2022

(54) IMAGE SENSOR AND IMAGING APPARATUS

(71) Applicant: SONY SEMICONDUCTOR SOLUTIONS CORPORATION, KANAGAWA (JP)

(72) Inventors: TOMOHIRO YAMAZAKI, KANAGAWA (JP); SHINICHIRO NOUDO, KANAGAWA (JP); IPPEI YOSHIBA, KANAGAWA (JP); HIROTAKA TAKESHITA, KANAGAWA (JP); TAKUJI MATSUMOTO, KANAGAWA (JP); OSAMU OKA, KANAGAWA (JP); TOSHIYA HASHIGUCHI, KANAGAWA (JP)

(21) Appl. No.: 17/429,412

(22) PCT Filed: Jan. 7, 2020
(86) PCT No.: PCT/JP2020/000109

§ 371 Date: Aug. 9, 2021

(30) Foreign Application Priority Data
Feb. 18, 2019 (JP) 2019-026440

(51) Int. Cl. H01L 27/146; H04N 5/369

(52) U.S. Cl. CPC H01L 27/14623; H01L 27/14645; H01L 27/14605; H04N 5/3696

(57) ABSTRACT

The purpose of the present disclosure is to improve the dynamic range of an image sensor including a polarization pixel.

The image sensor includes: a high-sensitivity pixel group; and a low-sensitivity pixel group. The high-sensitivity pixel group included in the image sensor includes a plurality of high-sensitivity pixels. The low-sensitivity pixel group included in the image sensor includes a plurality of low-sensitivity pixels. A polarization unit that causes incident light in a predetermined polarization direction to be transmitted therethrough is disposed in part of pixels of at least the high-sensitivity pixel group, of the high-sensitivity pixel group and the low-sensitivity pixel group.

### TECHNICAL FIELD

The present disclosure relates to an image sensor and an imaging apparatus. Specifically, the present disclosure relates to an image sensor and an imaging apparatus in which a polarization unit is disposed in a pixel.

### BACKGROUND ART

In the past, an image sensor in which a polarization pixel, which is a pixel for detecting polarization information of a subject, is disposed has been used. Light reflected from a subject is polarized in a direction corresponding to the plane of the subject. By detecting information regarding the polarized light, it is possible to, for example, acquire the three-dimensional shape of the subject. In such an image sensor, this polarization pixel and a color pixel for detecting color information of the subject are disposed and configured.

As such an image sensor, for example, an image sensor in which a plurality of polarization pixels is arranged in a grid pattern in a row direction and a column direction and a plurality of color pixels is arranged between the polarization pixels at positions shifted by a half pixel in the row direction and the column direction has been proposed (see, for example, Patent Literature 1.).

### CITATION LIST

### Patent Literature

Patent Literature 1: Japanese Patent Application Laid-open No. 2017-005111

### DISCLOSURE OF INVENTION

### Technical Problem

In the existing technology described above, there is a problem that the dynamic range at the time of imaging is narrow. A landscape or the like includes a subject with a wide range of luminance. When an image sensor having a small dynamic range is used for imaging such a landscape or the like, the image quality is deteriorated. Specifically, imaging of a subject including a region of high luminance and a region of low luminance is problematic, as in the case of imaging a landscape including a subject to which sunlight is directly applied and a subject of a shadowed portion. In a region of high luminance to which sunlight is directly applied, an image in which the tone is lost due to saturation of the image signal in the region, so-called blown out highlights, occur. Meanwhile, in a shadowed portion that is a region of low luminance, an image in which the tone is lost due to the image signal in the region becoming substantially black level, so-called blocked up shadows, occur. In either case, the obtained image lacks information regarding the subject in the region. As described above, in the above-mentioned existing technology, the image quality is deteriorated because the dynamic range is narrow.

The present disclosure has been made in view of the above-mentioned problem, and it is an object of the present disclosure to improve the dynamic range of an image sensor including a polarization pixel.

### Solution to Problem

The present disclosure has been made in view of the above-mentioned problem, and a first embodiment thereof is an image sensor, including: a high-sensitivity pixel group including a plurality of high-sensitivity pixels; and a low-sensitivity pixel group including a plurality of low-sensitivity pixels, in which a polarization unit that causes incident light in a predetermined polarization direction to be transmitted therethrough is disposed in part of pixels of at least the high-sensitivity pixel group, of the high-sensitivity pixel group and the low-sensitivity pixel group.

Further, in this first embodiment, the high-sensitivity pixel may be configured to have a size different from that of the low-sensitivity pixel.

Further, in this first embodiment, a plurality of the polarization units may include the polarization units having transmission axes in different directions when causing the incident light to be transmitted therethrough.

Further, in this first embodiment, the plurality of polarization units may include the polarization units configured to have the transmission axes in three or more directions.

Further, in this first embodiment, the plurality of polarization units may include the polarization units configured to have the transmission axes in two directions that are not perpendicular to each other.

Further, in this first embodiment, a plurality of the polarization units may have the transmission axes directed in the same direction.

Further, in this first embodiment, the plurality of polarization units may be configured to have the transmission axis in a direction perpendicular to a polarization direction of the incident light from a specific subject.

Further, in this first embodiment, the high-sensitivity pixel in which the polarization unit is disposed may be configured to have a sensitivity higher than that of the low-sensitivity pixel

Further, in this first embodiment, the polarization unit may include a wire grid including a plurality of strip conductors arranged at a predetermined pitch.

Further, in this first embodiment, a plurality of the polarization units may include the polarization units configured to have different transmittances.

Further, in this first embodiment, the polarization units may be configured to have different transmittances by changing widths of the strip conductors.

Further, in this first embodiment, the polarization units may be configured to have different transmittances by changing intervals between the strip conductors.

Further, in this first embodiment, the polarization unit disposed in the low-sensitivity pixel may be configured to have a transmittance different from that of the polarization unit disposed in the high-sensitivity pixel.

Further, in this first embodiment, the polarization unit disposed in the low-sensitivity pixel may be configured to have a transmittance lower than that of the polarization unit disposed in the high-sensitivity pixel.

Further, in this first embodiment, a plurality of pixel units may include pixels of the high-sensitivity pixel group and pixels of the low-sensitivity pixel group, the polarization unit being disposed in part of pixels of at least the high-sensitivity pixel group, of the pixels of the high-sensitivity pixel group and the pixels of the low-sensitivity pixel group, the plurality of pixel units including a plurality of the polarization units configured to have transmittances different from each other between the plurality of pixel units.

Further, a second embodiment of the present disclosure is an imaging apparatus, including: a high-sensitivity pixel group including a plurality of high-sensitivity pixels; a low-sensitivity pixel group including a plurality of low-sensitivity pixels; and a processing circuit that processes an image signal generated by the pixel, in which a polarization unit that causes incident light in a predetermined polarization direction to be transmitted therethrough is disposed in part of pixels of at least the high-sensitivity pixel group, of the high-sensitivity pixel group and the low-sensitivity pixel group.

By adopting such an embodiment, the effect that pixels of a high-sensitivity pixel group and a low-sensitivity pixel group, which are pixel groups having different sensitivities, constitute an image sensor and a pixel in which a polarization unit is disposed and a pixel in which a polarization unit is not disposed are mixed in the high-sensitivity pixel group is provided. Adjustment of the sensitivities of the pixels based on the presence or absence of the disposition of the polarization unit is assumed.

### BRIEF DESCRIPTION OF DRAWINGS

FIG. 1 is a diagram showing a configuration example of an image sensor according to an embodiment of the present disclosure.

FIG. 2 is a plan view showing a configuration example of an image sensor according to a first embodiment of the present disclosure.

FIG. 3 is a diagram showing an example of transmission of incident light in a polarization unit according to the embodiment of the present disclosure.

FIG. 4 is a diagram showing an example of polarization of incident light according to the embodiment of the present disclosure.

FIG. 5 is a diagram showing a configuration example of a pixel according to the first embodiment of the present disclosure.

FIG. 6 is a diagram showing a configuration example of a polarization unit according to the embodiment of the present disclosure.

FIG. 7 is a diagram showing an example of characteristics of the image sensor according to the first embodiment of the present disclosure.

FIG. 8 is a plan view showing a configuration example of an image sensor according to a modified example of the first embodiment of the present disclosure.

FIG. 9 is a plan view showing another configuration example of the image sensor according to the modified example of the first embodiment of the present disclosure.

FIG. 10 is a plan view showing a configuration example of an image sensor according to a second embodiment of the present disclosure.

FIG. 11 is a plan view showing a configuration example of an image sensor according to a third embodiment of the present disclosure.

FIG. 12 is a plan view showing a configuration example of an image sensor according to a fourth embodiment of the present disclosure.

FIG. 13 is a cross-sectional view showing a configuration example of a polarization unit according to the fourth embodiment of the present disclosure.

FIG. 14 is a cross-sectional view showing a configuration example of the polarization unit according to the fourth embodiment of the present disclosure.

FIG. 15 is a plan view showing a configuration example of an image sensor according to a fifth embodiment of the present disclosure.

FIG. 16 is a plan view showing a configuration example of an image sensor according to a sixth embodiment of the present disclosure.

FIG. 17 is a diagram showing a configuration example of a pixel according to the sixth embodiment of the present disclosure.

FIG. 18 is a block diagram showing a schematic configuration example of a camera that is an example of an imaging apparatus to which the present technology can be applied.

### MODE(S) FOR CARRYING OUT THE INVENTION

Next, embodiments for carrying out the present disclosure (hereinafter, referred to as embodiments) will be described with reference to the drawings. In the following drawings, the same or similar portions will be denoted by the same or similar reference symbols. Further, the embodiments will be described in the following order.

1. First Embodiment

2. Second Embodiment

3. Third Embodiment

4. Fourth Embodiment

5. Fifth Embodiment

6. Sixth Embodiment

7. Application example to camera

### 1. First Embodiment

[Configuration of Image Sensor]

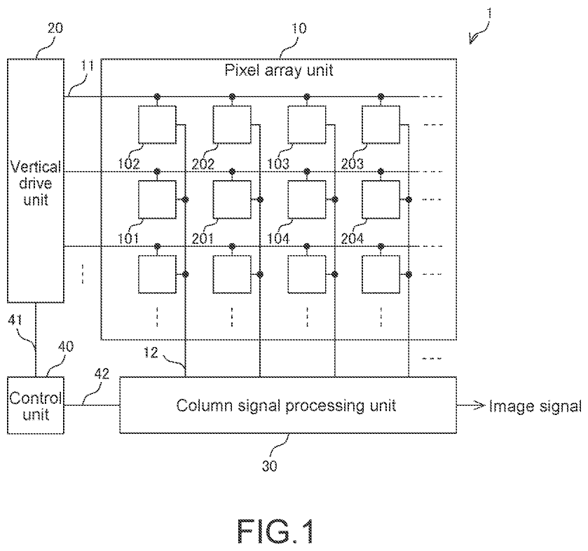

FIG. 1 is a diagram showing a configuration example of an image sensor according to an embodiment of the present disclosure. An image sensor 1 in the figure includes a pixel array unit 10, a vertical drive unit 20, a column signal processing unit 30, and a control unit 40.

The pixel array unit 10 is formed by arranging pixels 101 to 104 and pixels 201 to 204 in a two-dimensional grid pattern. Here, the pixel 101 and the like generate image signals corresponding to applied light. The pixel 101 and the like each include a photoelectric conversion unit for generating charges corresponding to the applied light. Further, the pixel 101 and the like each further include a pixel circuit. This pixel circuit generates an image signal based on the charges generated by the photoelectric conversion unit. The generation of the image signal is controlled by the control signal generated by the vertical drive unit 20 described below. In the pixel array unit 10, signal lines 11 and 12 are arranged in an X-Y matrix pattern. The signal line 11 is a signal line for transmitting the control signal of the pixel circuit in the pixel 101 or the like, arranged for each row of the pixel array unit 10, and commonly wired to the pixel 101 or the like arranged in each row. The signal line 12 is a signal line for transmitting the image signal generated by the pixel circuit of the pixel 101 or the like, arranged for each column of the pixel array unit 10, and commonly wired to the pixel 101 or the like arranged in each column. The photoelectric conversion unit and the pixel circuit are formed in a semiconductor substrate.

Note that the pixels 101 to 104 and the pixels 201 to 204 are configured to have different sensitivities. Here, the sensitivities represent ratios of the amount of incident light and the image signal output. The pixels 101 to 104 are configured to have relatively high sensitivities, and the pixels 201 to 204 are configured to have relatively low sensitivities. The configurations of the pixel 101 and the like will be described below in detail.

The vertical drive unit 20 generates control signals of the pixel circuits of the pixels 101 to 104 and the pixels 201 to 204. This vertical drive unit 20 transmits the generated control signal to the pixel 101 or the like via the signal line 11 in the figure. The column signal processing unit 30 processes the image signals generated by the pixels 101 to 104 and the pixels 201 to 204. This column signal processing unit 30 processes the image signal transmitted from the pixel 101 or the like via the signal line 12 in the figure. For example, analog-to-digital conversion in which an analog image signal generated in the pixel 101 or the like is converted into a digital image signal corresponds to the processing in the column signal processing unit 30. The image signal processed by the column signal processing unit 30 is output as an image signal of the image sensor 1. The control unit 40 controls the entire image sensor 1. This control unit 40 controls the image sensor 1 by generating and outputting control signals for controlling the vertical drive unit 20 and the column signal processing unit 30. The control signals generated by the control unit 40 are transmitted to the vertical drive unit 20 and the column signal processing unit 30 by signal lines 41 and 42, respectively. Note that the column signal processing unit 30 is an example of the processing circuit described in the claims.

[Configuration of Pixel Array Unit]

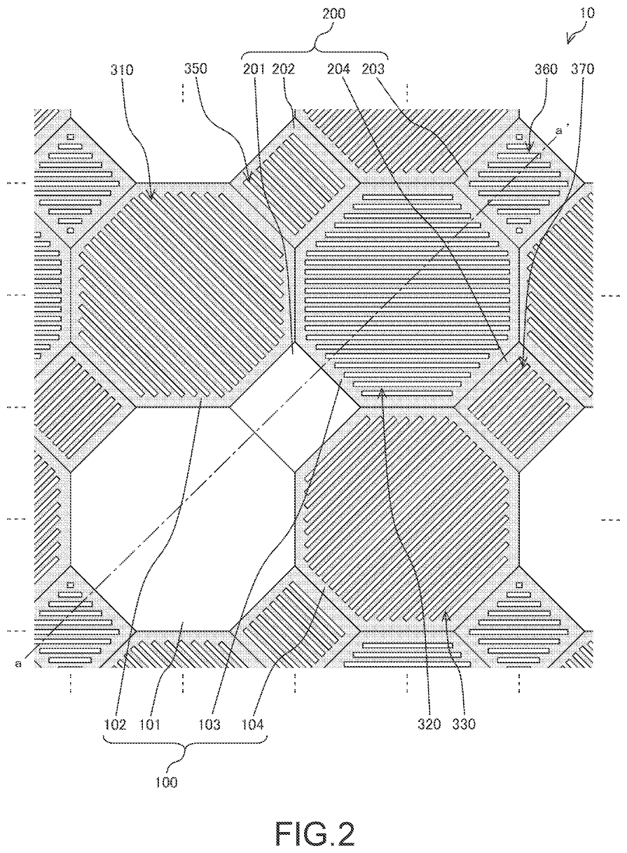

FIG. 2 is a plan view showing a configuration example of an image sensor according to the first embodiment of the present disclosure. FIG. 2 is a plan view showing a configuration example of the pixel array unit 10 of the image sensor 1.

As described above, the pixels 101 to 104 and the pixels 201 to 204 are arranged in the pixel array unit 10. In the figure, the octagons represent the pixels 101 to 104 and the rectangles represent the pixels 201 to 204. Polarization units 310, 320, and 330 are respectively disposed in the pixels 102 to 104 and polarization units 350, 360, and 370 are respectively disposed in the pixels 202 to 204, of these pixels. Here, each of the polarization units 310, 320, 330, 350, 360, and 370 causes incident light in a predetermined polarization direction, of light beams that have entered the pixels 102 to 104 and the pixels 202 to 204, to be transmitted therethrough to enter the corresponding photoelectric conversion unit.

The polarization unit 310 or the like may include, for example, a wire grid. The wire grid is formed by arranging a plurality of strip-shaped conductors (strip conductor 301 described below) at an equal pitch. In the figure, a hatched portion in a central portion of the polarization unit 310 or the like represents the strip conductor 301, and an outlined rectangular portion represents a gap between strip conductors 301. By arranging the plurality of strip conductors 301 in a slit pattern in this way, it is possible to transmit light in a polarization direction parallel to the direction in which the plurality of strip conductors 301 is arranged. This polarization direction of the light transmitted through the polarization unit 310 or the like is referred to as a transmission axis. Meanwhile, light in a polarization direction perpendicular to the directions in which the plurality of strip conductors 301 does not pass through the polarization unit 310 or the like, and is reflected. The polarization units 310, 320, and 330 are configured to have transmission axes in different directions. Similarly, also the polarization units 350, 360, and 370 have transmission axes in different directions. Specifically, assuming that the lateral direction of the plane of the figure is 0 degrees, the polarization units 310, 320, and 330 are configured to respectively have transmission axes of −45 degrees, 90 degrees, and 45 degrees clockwise. The same applies to also the polarization units 350, 360, and 370. As described above, the polarization units 310, 320, and 330, and the polarization units 350, 360, and 370 are configured to have the transmission axes in three or more directions.

As described above, the pixels 101 to 104 are pixels configured to have sensitivities higher than those of the pixels 201 to 204. These pixels 101 to 104 constitute a high-sensitivity pixel group 100. In this high-sensitivity pixel group 100, the pixels 102 to 104 in which the polarization unit 310 and the like are disposed and the pixel 101 in which the polarization unit is not disposed are mixed. Further, these pixels 101 to 104 are arranged in two rows and two columns.

The pixels 201 to 204 are pixels configured to have sensitivities lower than those of the pixels 101 to 104. These pixels 201 to 204 can be configured to have, for example, sizes different from those of the pixels 101 to 104. Specifically, as shown in the figure, the pixels 201 to 204 can be configured to have sizes smaller than those of the pixels 101 to 104. As a result, the pixels 201 to 204 can be configured to have sensitivities lower than those of the pixels 101 to 104. These pixels 201 to 204 constitute a low-sensitivity pixel group 200. In this low-sensitivity pixel group 200, the pixels 202 to 204 in which the polarization unit 350 or the like is disposed and the pixel 201 in which the polarization unit is not disposed are mixed.

The pixels 201 to 204 may each be disposed in the gap between the pixels 101 to 104 arranged in two rows and two columns. Specifically, as shown in the figure, the pixels 201 to 204 are disposed to be adjacent to sides of the octagonal pixels 101 to 104 other than sides where the octagonal pixels 101 to 104 are adjacent to each other. As a result, it is possible to arrange the pixels 101 to 104 and the pixels 201 to 204 having different sizes in the pixel array unit 10 to have high density. In the pixel array unit 10, eight pixels in units of pixels in four rows and four columns, which includes the pixels 101 to 104 and the pixels 201 to 204, are arranged in a two-dimensional grid pattern. The eight pixels constitute a pixel unit described below. Note that the pixels 101 to 104 are each an example of the high-sensitivity pixel described in the claims. The pixels 201 to 204 are each an example of the low-sensitivity pixel described in the claims.

[Transmission of Incident Light in Polarization Unit]

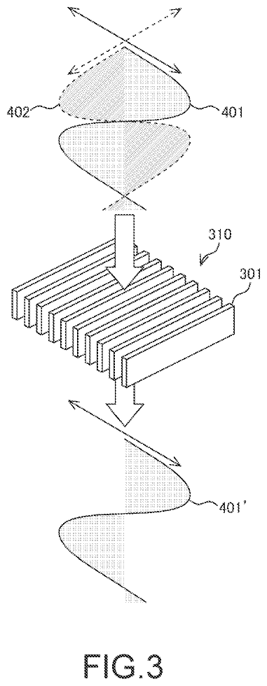

FIG. 3 is a diagram showing an example of transmission of incident light in the polarization unit according to the embodiment of the present disclosure. FIG. 3 is a diagram showing how incident light is transmitted through the polarization unit 310, 320, 330, 350, 360, or 370. The transmission of incident light in the polarization unit will be described by taking the polarization unit 310 in the figure as an example. Incident lights 401 and 402 in the figure are incident lights perpendicular to each other. The solid arrows in the figure represent the direction of oscillation of the electric field in the incident light 401, and the dashed arrows represent the direction of oscillation of the electric field in the incident light 402.

As shown in the figure, the polarization unit 310 is formed by arranging the plurality of strip conductors 301 at an equal pitch. The strip conductor 301 is formed of, for example, metal, and is a conductor formed in a linear shape or a rectangular parallelepiped shape. Free electrons in this strip conductor 301 oscillate following the electric field of the light that has entered the strip conductor 301 and radiate a reflected wave. The incident light 402 in the direction perpendicular to the arrangement direction of the plurality of strip conductors 301, i.e., in the direction parallel to the longitudinal direction of the strip conductor, radiates more reflected light because the amplitudes of the free electrons are increased. Therefore, the incident light 402 is not transmitted through the polarization unit 310 and is reflected.

Meanwhile, the radiation of reflected light from the strip conductor 301 is reduced in the incident light 401 in the direction parallel to the arrangement direction of the plurality of strip conductors 301, i.e., in the direction perpendicular to the longitudinal direction of the strip conductor 301. This is because the oscillation of free electrons is limited and the amplitude becomes small. Therefore, the incident light 401 is less attenuated by the polarization unit 310 and can be transmitted through the polarization unit 310. In the figure, this is represented as a transmission light 401′. As described above, the polarization unit 310 causes incident light in a predetermined polarization direction to be transmitted therethrough. The direction parallel to the arrangement direction of the plurality of strip conductors 301 corresponds to the above-mentioned transmission axis.

[Attenuation of Incident Light]

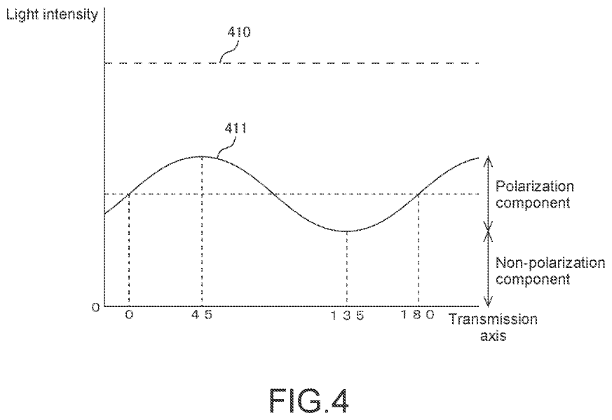

FIG. 4 is a diagram showing an example of attenuation of incident light according to the embodiment of the present disclosure. FIG. 4 is a diagram describing the attenuation by the polarization unit 310 in the case where incident light is applied to the pixel 102 or the like in which the polarization unit 310 or the like is disposed. The horizontal axis in the figure represents the transmission axis of the polarization unit 310. The unit of the horizontal axis is degrees. The vertical axis of the figure represents the light intensity. A dotted line 410 in the figure represents the incident light before being transmitted through the polarization unit 310, and a solid line 411 represents the incident light after being transmitted through the polarization unit 310. The incident light is attenuated to the intensity of 50% or less when being transmitted through the polarization unit 310. This is because the incident light having a polarization direction different from the transmission axis of the polarization unit 310 is reflected. Further, the intensity of the incident light transmitted through the polarization unit 310 changes in a sine wave shape at intervals of 180 degrees in accordance with the direction of the transmission axis of the polarization unit 310. In the example of the figure, the incident light transmitted through the polarization unit 310 is respectively maximized and minimized when the transmission axis is 45 degrees and 135 degrees.

Of the incident light transmitted through the polarization unit 310, a component that changes in a sine wave shape corresponds to a polarization component, and a component that does not change corresponds to a non-polarization component. The polarization component is incident light polarized in a predetermined direction, and is incident light reflected on a specific surface of a subject. For example, light reflected from glass or a water surface corresponds to the polarization component. The non-polarization component is incident light that is not polarized in a predetermined direction, and is, for example, incident light transmitted through glass. By removing the polarization component of the incident light on the pixel array unit 10, it is possible to remove the reflected light from glass and acquire a clear image of a subject on the opposite side of the glass. By acquiring polarization information regarding how incident light from a subject is polarized and performing image processing, it is possible to improve the image quality.

In the example of the figure (solid line 411), the polarization component is maximized when the transmission axis is 45 degrees. For this reason, it can be determined that the polarization component of the incident light is polarized in the direction of 45 degrees. This makes it possible to detect the direction of the normal of the place of the subject. Further, by subtracting the polarization component from the incident light to generate a non-polarization component, it is possible to acquire an image from which the above-mentioned effect of the reflected light has been removed. By acquiring the polarization information that is information regarding the polarization of incident light as described above, it is possible to acquire the three-dimensional shape of an image of a subject and improve the image quality. Since the polarization component changes in a sine wave shape, the polarization component can be detected and the polarization information can be acquired by disposing the polarization units having three or more transmission axes in the pixel array unit 10. That is, the polarization component can be detected by arranging the pixels 102 to 104 that include the polarization units 310, 320, and 330 having transmission axes different from each other. Similarly, the polarization component can be detected also by arranging the pixels 202 to 204 that include the polarization units 350, 360, and 370 having transmission axes different from each other.

Further, by disposing the polarization unit 310 or the like in a pixel, it is possible to adjust the sensitivity of the pixel. This is because part of incident light is shielded from light by the polarization unit 310 or the like and the sensitivity is reduced as described above. For this reason, the sensitivities of the pixels 102 to 104 in which the polarization units 310, 320, and 330 are arranged respectively are lower than the sensitivity of the pixel 101. Similarly, the sensitivities of the pixels 202 to 204 in which the polarization units 350, 360, and 370 are arranged respectively are lower than the sensitivity of the pixel 201. By disposing the polarization unit (polarization units 310, 320, and 330) in part (pixels 101 to 104) of the pixels of the high-sensitivity pixel group 100 as described above, it is possible to perform imaging by the pixels adjusted to have different sensitivities. It is possible to enlarge the dynamic range of the pixels of the high-sensitivity pixel group 100. Similarly, by disposing the polarization unit (the polarization units 350, 360, and 370) in part (pixels 201 to 204) of the pixels of the low-sensitivity pixel group 200, it is possible to enlarge the dynamic range of the pixels of the low-sensitivity pixel group 200.

Further, in the case where the pixels (pixels 102 to 104) in which the polarization unit is disposed, of the pixels of the high-sensitivity pixel group 100, are configured to have sensitivity higher than the sensitivity of the pixel (pixel 201) in which the polarization unit is not disposed, of the pixels of the low-sensitivity pixel group 200, it is possible to achieve a wider dynamic range. This can be achieved by adjusting the transmittance of the polarization unit and the sizes of the pixels of the high-sensitivity pixel group 100 and the low-sensitivity pixel group 200. Details of the dynamic range of the image sensor 1 will be described below.

[Configuration of Pixel]

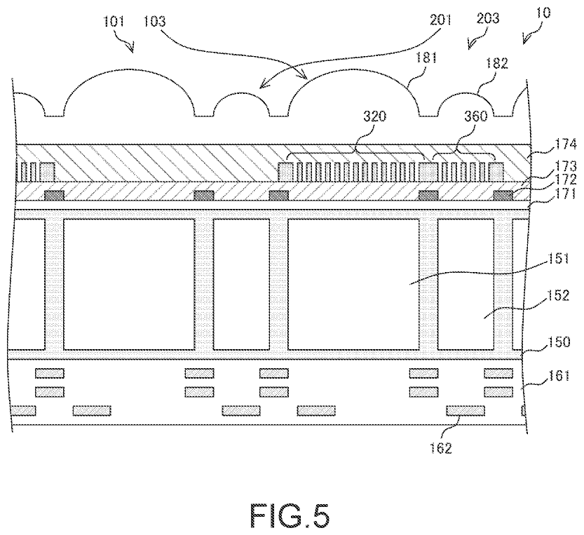

FIG. 5 is a diagram showing a configuration example of a pixel according to the first embodiment of the present disclosure. FIG. 5 is a cross-sectional view showing a configuration example of the pixel 101 and the like arranged in the pixel array unit 10, and is a cross-sectional view of the pixel array unit 10 taken along the line a-a′ in FIG. 2. The pixels 101 and 103 and the pixels 201 and 203 shown in the figure can have similar configurations except that they have different pixel sizes. The pixel 101 and the like include a semiconductor substrate 150, a wiring region including an insulation layer 161 and a wiring layer 162, insulation films 171 and 173, a light-shielding film 172, a flattening film 174, and on-chip lenses 181 and 182. Further, the pixels 103 and 203 respectively include the polarization units 320 and 360.

The semiconductor substrate 150 is a substrate on which a semiconductor portion of elements such as a photoelectric conversion unit and a pixel circuit of the pixel 101 or the like is formed. The semiconductor portion of elements such as a photoelectric conversion unit and a pixel circuit of the pixel 101 or the like is formed in a well region of the semiconductor substrate 150. For the sake of convenience, assumption is made that the semiconductor substrate 150 in the figure constitutes a p-type well region. By forming an n-type semiconductor region on this semiconductor substrate 150, a semiconductor portion such as a photoelectric conversion unit can be formed. In the semiconductor substrate 150 in the figure, n-type semiconductor regions 151 and 152 are described as examples. These semiconductor regions constitute a photoelectric conversion unit. Specifically, a p-n junction between the n-type semiconductor region and the p-type well region forms a photodiode to constitute a photoelectric conversion unit. Note that the n-type semiconductor region 151 is disposed in the pixels 101 to 104 of the high-sensitivity pixel group 100, and the n-type semiconductor region 152 is disposed in the pixels 201 to 204 of the low-sensitivity pixel group 100. To fit pixel size, the n-type semiconductor region 152 is configured to have a size smaller than that of the n-type semiconductor region 151 in accordance with the pixel size.

The wiring layer 162 is a wiring for transmitting a signal to the pixel 101 or the like. This wiring layer 162 can be formed of a metal such as copper (Cu). The insulation layer 161 isolates the wiring layer 162. This insulation layer 161 can be formed of, for example, silicon oxide (SiO—₂). The insulation layer 161 and the wiring layer 162 constitute a wiring region. This wiring region is formed adjacent to the surface of the semiconductor substrate 150.

The insulation film 171 is a film that is formed adjacent to the back surface of the semiconductor substrate 150 and insulates the semiconductor substrate 150. This insulation film 171 is formed of, for example, SiO₂, and insulates and protects the back surface side of the semiconductor substrate 150.

The light-shielding film 172 is a film that is disposed at a boundary portion of the pixel 101 or the like on the surface of the insulation film 171 and shields light obliquely entering from an adjacent pixel. This light-shielding film 172 can be formed of, for example, a metal such as tungsten (W).

The insulation film 173 is a film disposed adjacent to the insulation film 171 and the light-shielding film 172. This insulation film insulates and flattens the back surface side of the semiconductor substrate 150.

The polarization units 320 and 360 are disposed on the surface of the insulation film 172. As described above, they are formed by arranging the plurality of strip conductors 301 at an equal pitch.

The flattening film 174 is a film that flattens the back surface side of the pixel array unit 10. This flattening film 174 is disposed adjacent to the insulation film 173 to have a shape covering the polarization units 320 and 360, and flattens the surface on which the on-chip lens 181 or the like described below is formed.

The on-chip lenses 181 and 182 are lenses that collect incident light. The on-chip lenses 181 and 182 are formed in a hemispherical shape and disposed adjacent to the flattening film 174. The on-chip lenses 181 and 182 can be each formed of, for example, an organic material such as an acrylic resin or an inorganic material such as silicon nitride (SiN). Note that the on-chip lens 181 is disposed on the pixels 101 to 104 of the high-sensitivity pixel group 100, and the on-chip lens 182 is disposed on the pixels 201 to 204 of the low-sensitivity pixel group 100. The on-chip lens 182 is configured to have a size smaller than that of the on-chip lens 181 in accordance with the pixel size.

The image sensor 1 including the pixel array unit 10 in the figure corresponds to a back-illuminated image sensor in which incident light is applied from the back surface side of the semiconductor substrate 150. Note that the configuration of the image sensor 1 is not limited to this example. For example, the image sensor 1 may include a front-illuminated image sensor in which incident light is applied from the front surface side of the semiconductor substrate 150.

[Configuration of Polarization Unit]

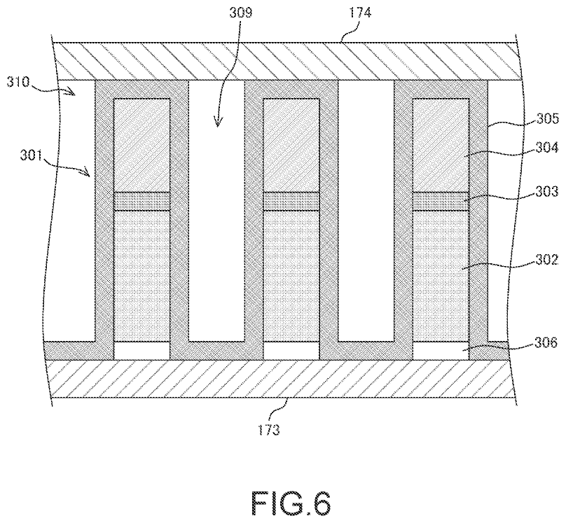

FIG. 6 is a diagram showing a configuration example of a polarization unit according to the embodiment of the present disclosure. FIG. 6 is a cross-sectional view showing a configuration example of the polarization unit 310. The configuration of a polarization unit will be described by taking the polarization unit 310 as an example. The polarization unit 310 in the figure is configured by disposing the plurality of strip conductors 301 between the insulation film 173 and the flattening film 174. Each of the strip conductors 301 includes a light-reflecting layer 302, an insulation layer 303, a light-absorbing layer 304, a protective layer 305.

The light-reflecting layer 302 reflects incident light. This light-reflecting layer 302 can be formed of an inorganic material having conductivity. For example, the light-reflecting layer 302 can be formed of a metal material such as Al, silver (Ag), gold (Au), Cu, platinum (Pt), molybdenum (Mo), chromium (Cr), titanium (Ti), nickel (Ni), W, iron (Fe), and tellurium (Te). Further, for example, the light-reflecting layer 302 can be formed of an alloy containing one of these metals or a semiconductor material such as silicon (Si) and germanium (Ge).

The light-absorbing layer 304 absorbs incident light. This light-absorbing layer 304 can be formed of a material similar to that of the light-reflecting layer 302, but it is suitable to use a material having a high absorption coefficient in incident light.

The insulation layer 303 is, for example, an insulator formed of SiO₂. This insulation layer 303 is disposed between the light-reflecting layer 302 and the light-absorbing layer 304, and adjusts the phase of the light reflected by the light-reflecting layer 302. Specifically, the insulation layer 303 adjusts the phase of the light reflected by the light-reflecting layer 302 to be opposite to the phase of the light reflected by the light-absorbing layer 304. Since the light whose phase has been adjusted by the insulation layer 303 and the light reflected by the light-absorbing layer 304 are in opposite phases, both of them are attenuated by interference. As a result, it is possible to reduce the reflection of light by the polarization unit 310. Further, the insulation layer 303 serves also as a base for the light-absorbing layer 304.

The protective layer 305 protects the light-reflecting layer 302, the insulation layer 303, and the light-absorbing layer 304 stacked in this order. This protective layer 305 can be formed of, for example, SiO₂.

The strip conductors 301 configured in this way are arranged at a predetermined pitch. A gap 309 is disposed between the adjacent strip conductors 301. This gap 309 can be formed by filling the space between the adjacent strip conductors 301 with a gas such as air. As a result, it is possible to improve the transmittance of the polarization unit 310.

Note that the configuration of the polarization unit 310 is not limited to this example. For example, the strip conductor 301 can be formed of only the light-reflecting layer 302.

[Characteristics of Image Sensor]

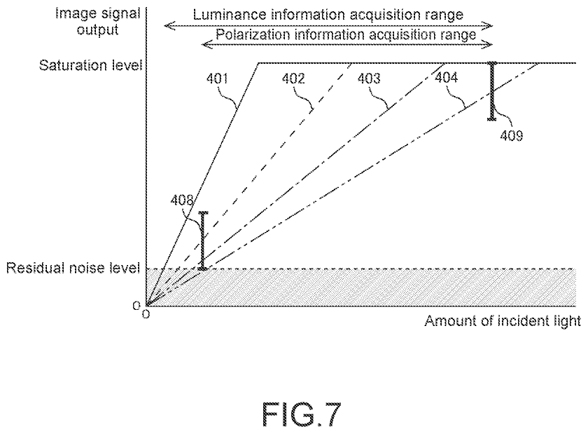

FIG. 7 is a diagram showing an example of characteristics of an image sensor according to the first embodiment of the present disclosure. FIG. 7 is a diagram showing the characteristics such as the dynamic range of the image sensor 1. The vertical axis of the figure represents the image signal output generated by pixels arranged in the pixel array unit 10, and the horizontal axis represents the amount of incident light of the pixels. In the figure, a graph 401 of the solid line represents the characteristics of the pixel 101 that is a pixel in which the polarization unit is not disposed, of the pixels of the high-sensitivity pixel group 100. A graph 402 of a dotted line represents the characteristics of the pixels 102 to 104 that are pixels in which the polarization unit is disposed, of the pixels of the high-sensitivity pixel group 100. A graph 403 of a dot-dash line represents the characteristics of the pixel 201 that is a pixel in which the polarization unit is not disposed, of the pixels of the low-sensitivity pixel group 200. A graph 404 of a two-dot chain line represents the characteristics of the pixels 202 to 204 that are pixels in which the polarization unit is disposed, of the pixels of the low-sensitivity pixel group 200.

In either pixel, the image signal output increases as the amount of incident light increases. However, since the holding amount of charges generated by photoelectric conversion in the pixel 101 or the like is limited, there is a predetermined saturation level in the image signal output. Note that the residual noise level in the figure is an output level of the noise generated in the image sensor 1 regardless of incident light. In the case where the image signal output generated by the pixel 101 or the like is less than or equal to the residual noise level, the image signal based on the luminance of a subject is buried in the noise, and the luminance of a subject cannot be measured. The pixel 101 or the like can be used in the range of the amount of incident light corresponding to the image signal between the residual noise level and the saturation level.

The graphs 401 to 404 have slopes corresponding to the sensitivities of the respective pixels. The pixel 101 of the high-sensitivity pixel group 100 in which the polarization unit is not disposed has the highest sensitivity. Subsequently, the sensitivity decreases in the order of the pixels 102 to 104 of the high-sensitivity pixel group 100 in which the polarization unit 310 or the like is disposed, the pixel 201 of the low-sensitivity pixel group 200 in which the polarization unit is not disposed, and the pixels 202 to 204 of the low-sensitivity pixel group 200 in which the polarization unit 320 or the like is disposed. In the pixel having a high sensitivity, although image signals larger than or equal to the residual noise level can be output even at a low amount of incident light, also the amount of incident light reaching the saturation level is also reduced and the dynamic range is narrowed. On the contrary, in the pixel having a low sensitivity, although image signals corresponding to the amount of incident light can be output even at a high amount of incident, a low amount of incident light cannot be supported.

In this regard, by arranging these four types of pixels, it is possible to achieve a wide dynamic range. The luminance information acquisition range in the figure corresponds to the dynamic range in the case where the four types of pixels are used. For example, for a subject of high luminance, such as a subject to which direct sunlight is applied, it is possible to prevent, by performing imaging by the pixels 202 to 204 corresponding to the graph 404, blown out highlights from occurring. Meanwhile, for a subject of low luminance, such as a portion shaded by an object, it is possible to prevent, by performing imaging by the pixel 101 corresponding to the graph 401, blocked up shadows from occurring.

Further, by using image signals of the four types of pixels, it is possible to improve the resolution at the time of converting the amount of incident light into an image signal. As described in FIG. 1, the image signal output from the pixel 101 or the like is analog-to-digital converted into a digital image signal in the column signal processing unit 30. Therefore, the image signal is output from the image sensor 1 as a digital image signal having a resolution corresponding to the number of bits. Since the image signals are converted into digital signals having the same number of bits in all pixels arranged in the pixel array unit 10, the resolution of the detectable amount of incident light becomes lower as the pixel having a relatively low sensitivity is capable of coping with a wider range of the amount of incident light, and the image quality is deteriorated. In this regard, by switching and using image signals of the four types of pixels in accordance with the amount of incident light of a subject, it is possible to reduce the effect of the reduction of the resolution.

Specifically, for a subject of a low amount of incident light, an image signal generated by the pixel 101 corresponding to the graph 401 is used. Image signals generated by the pixels 102 to 104 corresponding to the graph 402 are used in the amount of incident light at which the image signal of the pixel 101 reaches approximately the saturation level. Similarly, the image signal is switched to an image signal generated by the pixel 201 corresponding to the graph 403 in the amount of incident light at which the image signals of the pixels 102 to 104 reach substantially the saturation level. The image signal is switched to image signals generated by the pixels 202 to 204 corresponding to the graph 404 in the amount of incident light at which the image signal of the pixel 201 reaches substantially the saturation level. By switching image signals of the four types of pixels, i.e., the pixels 101 to 104 and the pixels 201 to 204, and performing imaging in this way, it is possible to reduce the deterioration of image quality due to the reduction of the resolution while ensuring a wide dynamic range. For example, when a subject whose luminance or color tone gradually changes is imaged, the change of image signals can be smoothed and an image of a high reproducibility for a subject can be obtained.

Further, the graphs 402 and 409 respectively represent characteristics of the pixels 102 to 104 and the pixels 202 to 204. These correspond to the characteristics of pixels in which the polarization unit is disposed. As described in FIG. 4, the image signal of the pixel in which the polarization unit is disposed includes a polarization component whose output periodically changes. This polarization component is described as varying widths 408 and 409 in the graphs 402 and 404, respectively. The range of the amount of incident light taking into account the variation is the polarization information acquisition range in the figure. Even in the case where the polarization information is acquired, a wide dynamic range can be ensured by switching and using image signals of the pixels 101 to 104 corresponding to the graph 402 and the pixels 202 to 204 corresponding to the graph 404.

### Modified Example

In the above-mentioned image sensor 1, the polarization unit is disposed in part of pixels of the high-sensitivity pixel group 100 and the low-sensitivity pixel group 200, but the polarization unit of one of the pixel groups may be omitted.

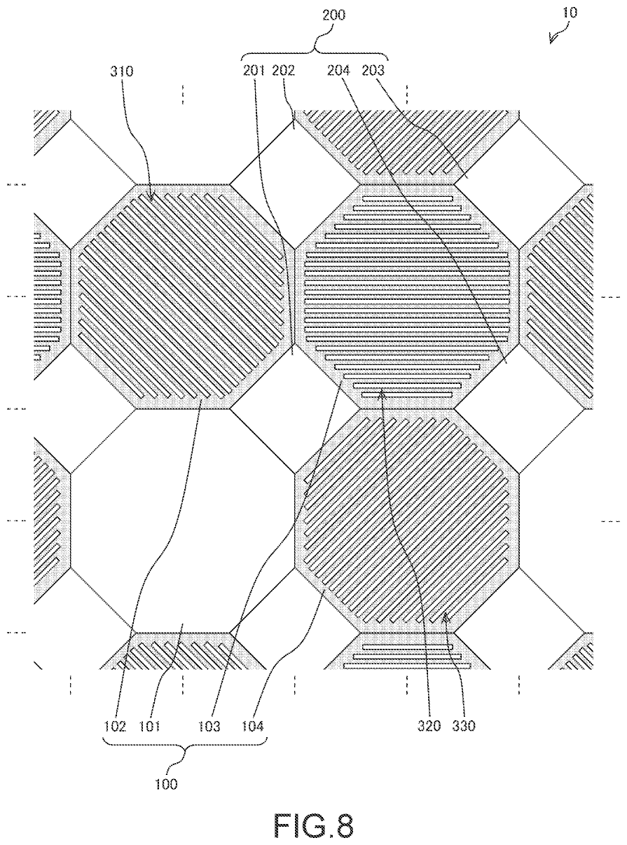

FIG. 8 is a plan view showing a configuration example of an image sensor according to a modified example of the first embodiment of the present disclosure. The image sensor 1 in the figure is different from the image sensor 1 in FIG. 2 in that the polarization units 350 to 370 are omitted in the pixels 202 to 204.

In the image sensor 1 in the figure, the polarization unit is disposed in part (pixels 102 to 104) of pixels of the high-sensitivity pixel group 100. The polarization information of a subject can be acquired by these pixels 102 to 104. Further, imaging can be performed by pixels of three kinds of sensitivities, i.e., the pixel 101, the pixels 102 to 104, and the pixels 201 to 204.

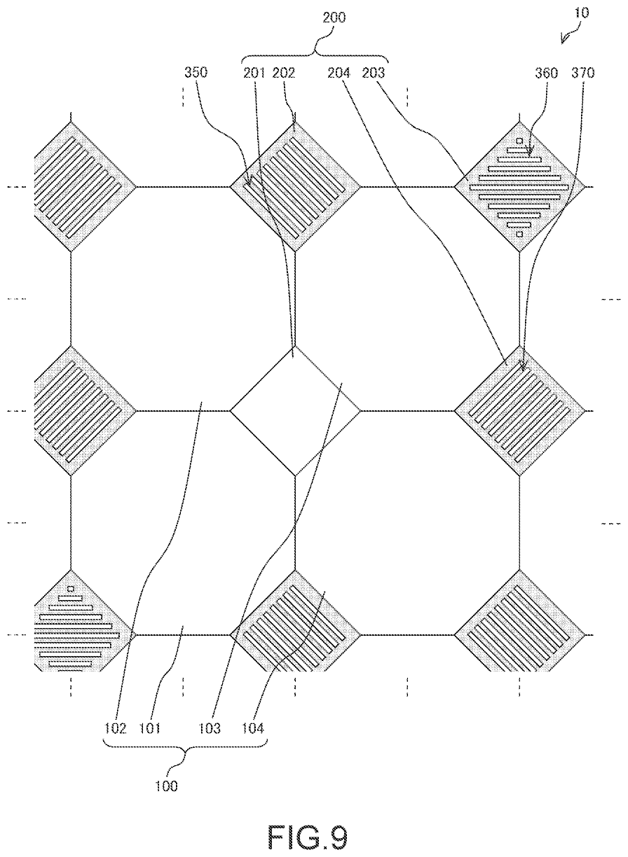

FIG. 9 is a plan view showing another configuration example of the image sensor according to the modified example of the first embodiment of the present disclosure. The image sensor 1 in the figure is different from the image sensor 1 in FIG. 2 in that the polarization units 310 to 330 are omitted in the pixels 102 to 104.

In the image sensor 1 in the figure, the polarization unit is disposed in part (pixels 202 to 204) of pixels of the low-sensitivity pixel group 200. The polarization information of a subject can be acquired by these pixels 202 to 204. Further, imaging can be performed by pixels of three kinds of sensitivities, i.e., the pixels 101 to 104, the pixel 201, and the pixels 202 to 204. The arrangement of pixels as shown in the figure can also be applied to, for example, part of areas of the pixel array unit 10 of the image sensor 1 described in FIG. 2, e.g., the peripheral portion. This is because the polarization unit is not disposed in the pixel of the high-sensitivity pixel group 100 and thus the resolution of a subject of low luminance can be improved.

As described above, the image sensor 1 according to the first embodiment of the present disclosure includes pixels of the high-sensitivity pixel group 100 and the low-sensitivity pixel group 200, and a polarization unit is disposed in part of pixels of at least the high-sensitivity pixel group 100. As a result, a plurality of pixels having different sensitivities is disposed in the pixel array unit 10, and it is possible to improve the dynamic range of the image sensor 1.

### 2. Second Embodiment

In the image sensor 1 according to the above-mentioned first embodiment, polarization units configured to have transmission axes in three directions are disposed in the pixels. Meanwhile, the image sensor 1 according to a second embodiment of the present disclosure is different from that in the above-mentioned first embodiment in that polarization units configured to have transmission axes in two directions are disposed in the pixels.

[Configuration of Pixel Array Unit]

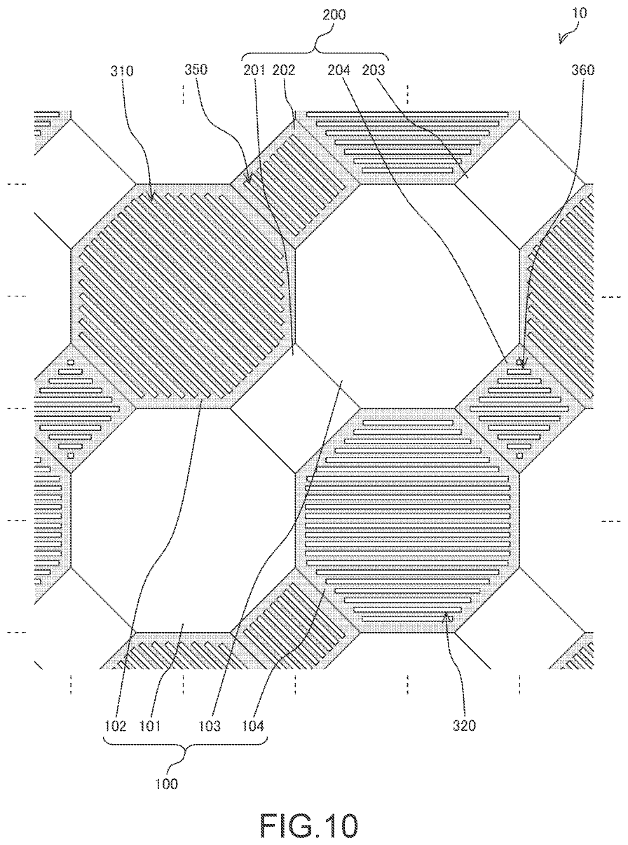

FIG. 10 is a plan view showing a configuration example of the image sensor according to the second embodiment of the present disclosure. FIG. 10 is a plan view showing a configuration example of the pixel array unit 10 of the image sensor 1, similarly to FIG. 2. The image sensor 1 in the figure is different from the image sensor 1 described in FIG. 2 in that the polarization units 310 and 320 configured to have transmission axes in two directions and the polarization units 350 and 360 configured to have transmission axes in two directions are disposed in pixels.

Similarly to the image sensor 1 in FIG. 2, the polarization units 310 and 350 are respectively disposed in the pixels 102 and 202. Meanwhile, the polarization units of the pixels 103 and 203 are omitted, and the polarization units 320 and 360 are respectively disposed in the pixels 104 and 204. The polarization units 310 and 320 disposed in the image sensor 1 in the figure have transmission axes that differ in the direction by 45 degrees. Similarly, also the polarization units 350 and 360 have transmission axes that differ in the direction by 45 degrees. As described above, the image sensor 1 in the figure includes pixels in which polarization units configured to have transmission axes in two directions that are not perpendicular to each other are disposed.

As described in FIG. 4, in order to detect the polarization component that changes in a sine wave shape, there is a need for polarization units having three or more transmission axes. In this regard, an image signal corresponding to the direction of the third transmission axis is generated. This can be calculated by calculation of an image signal of a pixel in which the polarization unit is not disposed and ab image signal of a pixel in which the polarization unit is disposed. For example, by subtracting the image signal of the pixel 102 from the image signal compensated for the image signal of the pixel 101 in accordance with the sensitivity, it is possible to calculate a polarization component in the direction that differs by 90 degrees from the transmission axis of the polarization unit 310 disposed in the pixel 102. At this time, by configuring the polarization unit 310 of the pixel 102 and the polarization unit 320 of the pixel 104 in polarization directions that are not perpendicular to each other, it is possible to set the calculated polarization direction of the image signal to a polarization direction different from that of the image signal of the pixel 104. Further, the image signal of the pixel 104 may be subtracted from the compensated image signal of the pixel 103.

As described above, the image signal in the third polarization direction can be calculated from the image signals of the pixels 102 and 104 and the image signals of the pixels 101 and 103. Similarly, the image signal in the third polarization direction can be calculated from the image signals of the pixels 202 and 204 and the image signals of the pixels 201 and 203. As a result, it is possible to detect the polarization component of incident light.

Since the other configurations of the image sensor 1 are the same as those of the image sensor 1 described in the first embodiment of the present disclosure, description thereof is omitted.

As described above, in the image sensor 1 according to the second embodiment of the present disclosure, polarization units configured to have transmission axes in two directions that are not perpendicular to each other are disposed in pixels to acquire the polarization information of a subject. As a result, it is possible to simplify the configuration of the image sensor 1.

### 3. Third Embodiment

In the image sensor 1 according to the above-mentioned first embodiment, the polarization units configured to have transmission axes in three directions are disposed in pixels. Meanwhile, the image sensor 1 according to the third embodiment of the present disclosure is different from that in the above-mentioned first embodiment in that the polarization unit configured to have a transmission axis in one direction is disposed in a pixel.

[Configuration of Pixel Array Unit]

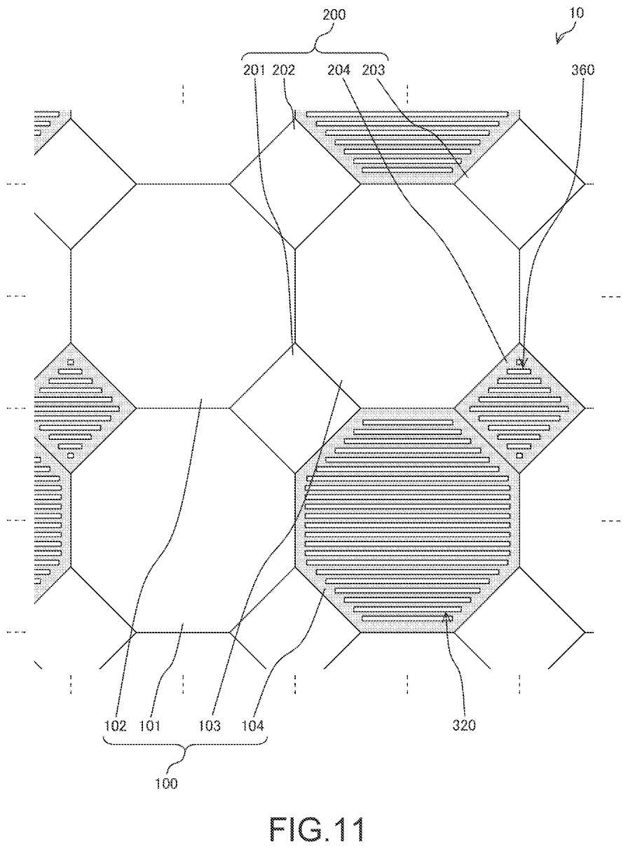

FIG. 11 is a plan view showing a configuration example of an image sensor according to a third embodiment of the present disclosure. FIG. 11 is a plan view showing a configuration example of the pixel array unit 10 of the image sensor 1, similarly to FIG. 2. The image sensor 1 in the figure is different from the image sensor 1 described in FIG. 2 in that the polarization units 320 and 360 configured to have transmission axes in the same direction are disposed in pixels.

As described above, the incident light reflected from a specific surface of a subject is polarized in a specific direction. In this regard, the image of the subject can be removed by shielding the incident light in the specific direction. For example, in the case where incident light including reflected light from a puddle on a road is imaged by the image sensor 1, the polarization units 320 and 360 are configured to have transmission axes perpendicular to the polarization direction of the reflected light from the puddle. As a result, the reflected light from the puddle is shielded, and the image reflected by the puddle can be removed. It is possible to acquire the state of the road under the water surface of the puddle. In this way, by disposing, in a pixel, the polarization unit configured to have a transmission axis perpendicular to the polarization direction of incident light to be removed, it is possible to remove an unnecessary image.

Since the other configurations of the image sensor 1 are the same as those of the image sensor 1 described in the first embodiment of the present disclosure, description thereof is omitted.

As described above, the image sensor 1 according to the third embodiment of the present disclosure is capable of shielding incident light in an unnecessary polarization direction to improve the image quality by disposing the polarization units 320 and 360 configured to have transmission axes in one direction in pixels.

### 4. Fourth Embodiment

In the image sensor 1 according to the above-mentioned first embodiment, the polarization unit 310 or the like in which the strip conductors 301 having the same width are arranged is disposed in the pixel. Meanwhile, the image sensor 1 according to a fourth embodiment of the present disclosure is different from that in the above-mentioned first embodiment in that a polarization unit in which the strip conductors 301 having different widths are arranged is disposed in the image sensor 1 according to the fourth embodiment.

[Configuration of Pixel Array Unit]

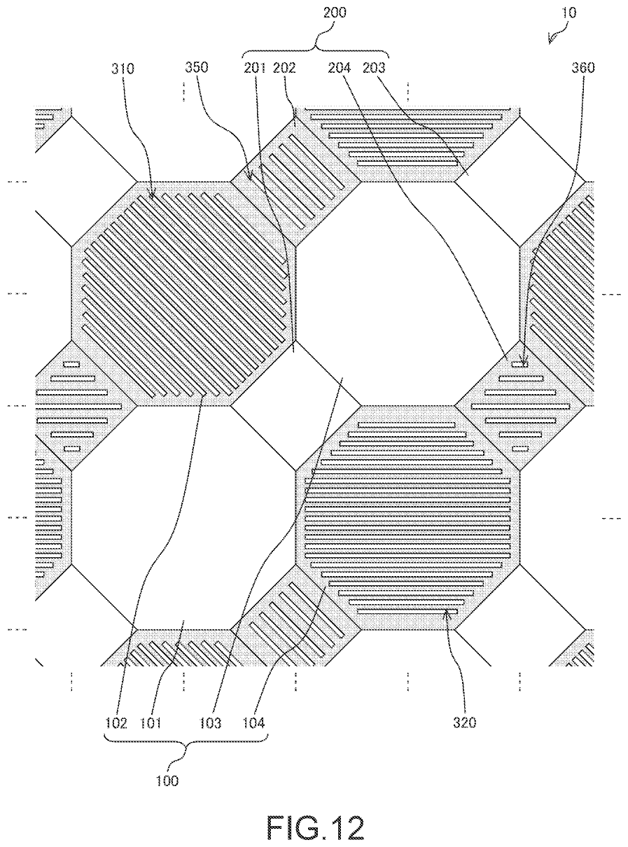

FIG. 12 is a plan view showing a configuration example of an image sensor according to the fourth embodiment of the present disclosure. FIG. 12 is a plan view showing a configuration example of the pixel array unit 10 of the image sensor 1, similarly to FIG. 10. The image sensor 1 in the figure is different from the image sensor 1 described in FIG. 10 in that the polarization units 310 and 320 and the polarization units 350 and 360 in which the strip conductors 301 having different widths are arranged.

The polarization units 350 and 360 in the figure are formed by arranging the strip conductors 301 having widths different from those of the polarization units 310 and 320. Specifically, the strip conductors 301 of the polarization units 350 and 360 are configured to have widths larger than those of the polarization units 310 and 320. That is, the strip conductors 301 of the polarization units 350 and 360 are configured to have widths larger than those of the polarization units 350 and 360 in FIG. 1. As a result, it is possible to adjust the transmittance of the polarization unit. Here, the transmittance represents the ratio of the transmission light to the incident light of the polarization unit. In the figure, the transmittances of the polarization units 350 and 360 can be reduced. The sensitivities of the pixels 202 and 204 in which these polarization units 350 and 360 are disposed can be reduced to adjust the dynamic range.

[Configuration of Polarization Unit]

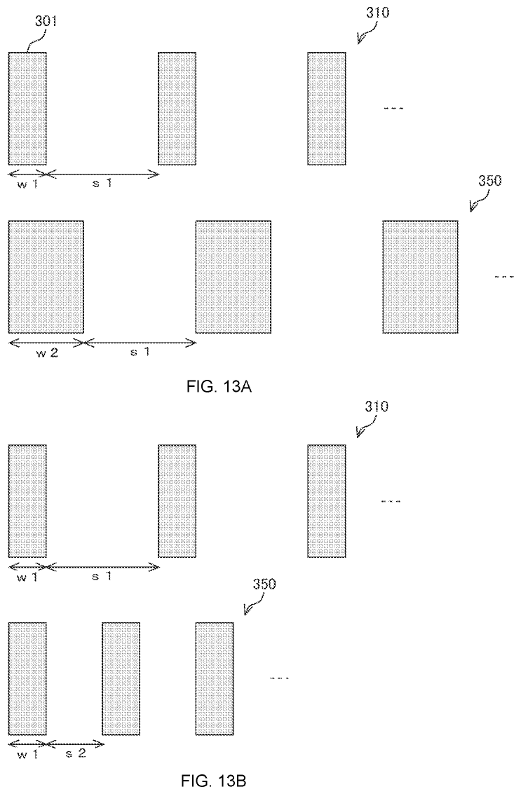

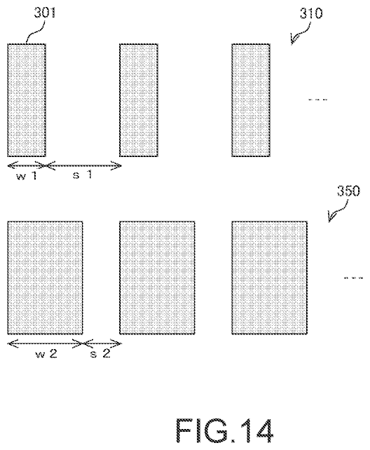

FIG. 13 and FIG. 14 are each a cross-sectional view showing a configuration example of a polarization unit according to the fourth embodiment of the present disclosure. The figures are each a cross-sectional view showing a configuration example of the polarization units 310 and 350. The rectangles in the figures represent the strip conductors 301.

Part A of FIG. 13 is a diagram showing an example of the case where the width of the strip conductor 301 of the polarization unit 350 is made larger than that of the strip conductor 301 of the polarization unit 310. Reference symbols w1 and w2 in the figure respectively represent the width of the strip conductor 301 in the polarization units 310 and 350. Part A of the figure shows an example in which the strip conductor 301 of the polarization unit 350 is configured to have a width that is substantially twice as large as that of the strip conductor 301 of the polarization unit 310. Further, a reference symbol s1 represents the interval between the strip conductors 301 in the polarization units 310 and 350. The plurality of strip conductors 301 in the polarization units 310 and 350 in Part A of the figure is arranged at the same interval s1. For this reason, in the polarization unit 350 in the figure, the area of the strip conductor 301 with respect to the surface to which incident light is applied is larger than that in the polarization unit 310, and the transmittance is reduced.

Part B of FIG. 13 is a diagram showing an example of the case where the interval between the strip conductors 301 in the polarization unit 350 is smaller than that in the polarization unit 310. A reference symbol s2 in the figure represents the interval between the strip conductors 301 arranged in the polarization unit 350. Part B of FIG. 13 shows an example in which the strip conductors 301 of the polarization unit 350 are arranged at an interval that is substantially half the interval between the strip conductors 301 of the polarization unit 350. Note that the strip conductors 301 of the polarization unit 310 and 350 have the same width w1. Similarly to Part A of FIG. 13, in the polarization unit 350 in Part B of FIG. 13, the area of the strip conductor 301 with respect to the surface to which incident light is applied is larger, and the transmittance is reduced as compared with the polarization unit 310. By adjusting one of the width and the interval of the strip conductor 301 as described above, it is possible to adjust the sensitivities of the pixels 202 and 204 in which the strip conductor 301 is disposed.

Note that FIG. 14 is a diagram showing an example of the case where the width of the strip conductor 301 of the polarization unit 350 is made larger than that of the strip conductor 301 of the polarization unit 310 and the interval between the strip conductors 301 of the polarization unit 350 is made smaller than that in the polarization units 310. The reference symbols w1 and w2 and the reference symbols s1 and s2 in the figure represent the width and the interval of the strip conductor 301, similarly to FIG. 13. FIG. 14 shows an example in which the strip conductors 301 of the polarization unit 350 are each configured to have a width that is substantially twice as large as that of the strip conductor 301 of the polarization unit 310 and arranged at an interval that is substantially half the interval between the strip conductors 301 of the polarization unit 350. For this reason, the strip conductors 301 of the polarization unit 350 are arranged at substantially the same pitch as that in the polarization unit 310. Also in this case, similarly to Part A of FIG. 13, in the polarization unit 350 in the figure, the area of the strip conductor 301 with respect to the surface to which incident light is applied is larger, and the transmittance is reduced as compared with the polarization unit 310. Also in the case where the width and interval of the arranged strip conductor 301 are simultaneously adjusted as described above, it is possible to adjust the sensitivities of the pixels 202 and 204 in which the strip conductor 301 is disposed.

Since the other configurations of the image sensor 1 are the same as those of the image sensor 1 described in the first embodiment of the present disclosure, description thereof is omitted.

As described above, in the image sensor 1 according to the fourth embodiment of the present disclosure, the transmittance is adjusted by changing the width and the interval of the strip conductor 301 of the polarization units 350 and 360. As a result, it is possible to adjust the sensitivities of the pixels 202 and 204 and adjust the dynamic range of the image sensor 1.

### 5. Fifth Embodiment

In the image sensor 1 according to the above-mentioned first embodiment, the polarization unit 310 or the like in which the strip conductors 301 having the same width are arranged is disposed in the pixel. Meanwhile, the image sensor 1 according to the fifth embodiment of the present disclosure is different from that in the above-mentioned first embodiment in that a polarization unit in which the strip conductors 301 having width different for each pixel unit including a plurality of pixels 101 and the like are arranged is disposed.

[Configuration of Pixel Array Unit]

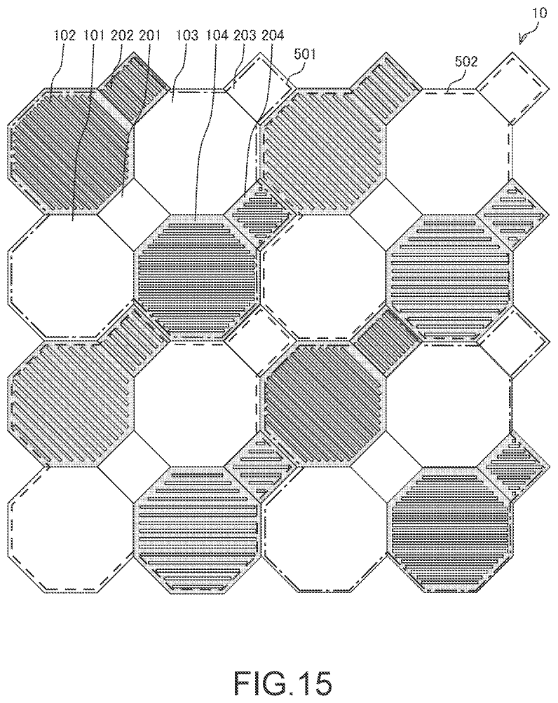

FIG. 15 is a plan view showing a configuration example of the image sensor according to the fifth embodiment of the present disclosure. FIG. 15 is a plan view showing a configuration example of the pixel array unit 10 of the image sensor 1, similarly to FIG. 10. The image sensor 1 in the figure is different from the image sensor 1 described in FIG. 10 in that the polarization units 310 and 320 and the polarization units 350 and 360 having widths different for each pixel unit are disposed. Here, the pixel unit represents a block including pixels of the high-sensitivity pixel group 100 and pixels of the low-sensitivity pixel group 200. Further, the polarization unit is disposed in part of the pixels of at least the high-sensitivity pixel group 100, of the pixels of the pixel unit.

In the figure, an example of the pixel unit including pixels in four rows and four columns, i.e., the four pixels (pixels 101 to 104) of the high-sensitivity pixel group 100 and the four pixels (pixels 201 to 204) of the low-sensitivity pixel group 200, is shown. The plurality of pixels 101 and the like surrounded by a dot-dash line in the figure constitutes a pixel unit 501, and the plurality of pixels 101 and the like surrounded by a dotted line constitutes a pixel unit 502.

Further, the polarization units disposed in the pixels of the pixel units 501 and 502 include the strip conductors 301 having different widths. Specifically, in each of the polarization units disposed in the pixels 102, 104, 202, and 204 of the pixel unit 502, the strip conductors 301 having widths larger than those of the polarization units disposed in the pixels 102, 104, 202, and 204 of the pixel unit 501 re disposed. The pixel array unit 10 in the figure is formed by alternately arranging such pixel units 501 and 502. As a result, it is possible to adjust, for each pixel unit, the transmittance of the pixel in which the polarization unit is disposed. Note that similarly to Part B of FIG. 13, the strip conductors 301 with different intervals may be arranged for each pixel unit and a configuration similar to that in FIG. 14 may be adopted.

Since the other configurations of the image sensor 1 are the same as those of the image sensor 1 described in the first embodiment of the present disclosure, description thereof is omitted.

As described above, in the image sensor 1 according to the fifth embodiment of the present disclosure, polarization units having transmittances different for the pixel units 501 and 502 are disposed, and thus it is possible to adjust the dynamic range.

### 6. Sixth Embodiment

The image sensor 1 according to the above-mentioned first embodiment generates an image signal corresponding to luminance of a subject. Meanwhile, the image sensor 1 according to a sixth embodiment of the present disclosure is different from that in the above-mentioned first embodiment in that an image signal corresponding to the luminance and chromaticity of a subject is generated.

[Configuration of Pixel Array Unit]

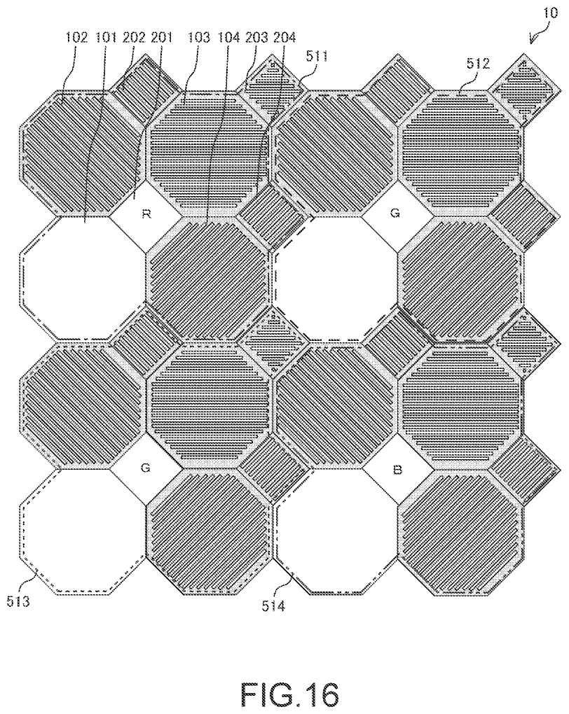

FIG. 16 is a plan view showing a configuration example of the image sensor according to the sixth embodiment of the present disclosure. FIG. 16 is a plan view showing a configuration example of the pixel array unit 10 of the image sensor 1, similarly to FIG. 2. The image sensor 1 in the figure is different from the image sensor 1 in FIG. 2 in that a color filter is disposed in the pixel 101 or the like. Here, the color filter is an optical filter that causes incident light of a predetermined wavelength, of incident light of the pixel, to be transmitted therethrough and applies the transmitted incident light to a photoelectric conversion unit.

In the image sensor 1 in the figure, a different color filter is disposed for each pixel unit. A color filter that causes red light to be transmitted therethrough is disposed on the pixel 101 and the like of a pixel unit 511, and a color filter that causes green light to be transmitted therethrough is disposed on the pixel 101 and the like of pixel units 512 and 513. Further, a color filter that causes blue light to be transmitted therethrough is disposed on the pixel 101 and the like of a pixel unit 514. The characters “R”, “G” and “B” shown in the figure each indicate the type of the color filter disposed on the pixel of the pixel unit. That is, “R”, “G”, and “B” respectively represent pixel units in which color filters that causes red light, green light, and blue light to be transmitted therethrough are disposed. The image sensor 1 in the figure is formed by arranging such four pixel units in a two-dimensional grid pattern. Further, the arrangement of the pixel units 511 to 514 shown in the figure can adopt, for example, a configuration in which color filters that causes green light to be transmitted therethrough are arranged in a checkerboard shape and color filters that causes red light to be transmitted therethrough and color filters that causes blue light to be transmitted through are arranged between the color filters that causes green light to be transmitted therethrough. Such an array is referred to as a Bayer array.

[Configuration of Pixel]

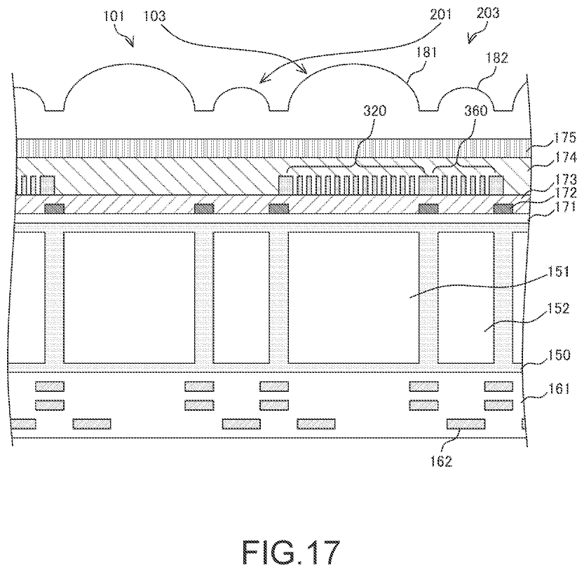

FIG. 17 is a diagram showing a configuration example of a pixel according to the sixth embodiment of the present disclosure. FIG. 17 is a cross-sectional view showing a configuration example of the pixel 101 and the like, similarly to FIG. 5. The pixel 101 and the like in the figure are different from the pixel 101 and the like described in FIG. 5 in that a color filter 175 is disposed. The color filter 175 can be disposed between the flattening film 174 and the on-chip lenses 181 and 182.

Since the other configurations of the image sensor 1 are the same as those of the image sensor 1 described in the first embodiment of the present disclosure, description thereof is omitted.

As described above, in the image sensor 1 according to the sixth embodiment of the present disclosure, it is possible to detect the chromaticity of a subject by disposing the color filter 175 and output a color image signal.

### 7. Application Example to Camera

The technology according to the present disclosure (the present technology) is applicable to a variety of products. For example, the present technology may be realized as an image sensor mounted on an imaging apparatus such as a camera.

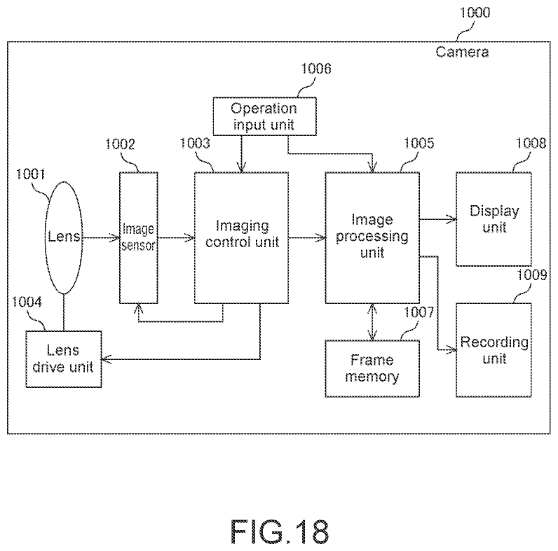

FIG. 18 is a block diagram showing a schematic configuration example of a camera that is an example of an imaging apparatus to which the present technology can be applied. A camera 1000 includes a lens 1001, an image sensor 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. This lens 1001 collects light from a subject and causes the collected light to enter the image sensor 1002 described below to form an image of the subject.

The image sensor 1002 is a semiconductor device that images the light from a subject collected by the lens 1001. This image sensor 1002 generates an analog image signal corresponding to the applied light, converts the analog image signal into a digital image signal, and outputs the digital image signal.

The imaging control unit 1003 controls imaging in the image sensor 1002. This imaging control unit 1003 controls the image sensor 1002 by generating a control signal and outputting the control signal to the image sensor 1002. Further, the imaging control unit 1003 is capable of performing autofocusing in the camera 1000 on the basis of the image signal output from the image sensor 1002. Here, the autofocusing is a system that detects a focal position of the lens 1001 and automatically adjusts the focal position. As this autofocusing, a method of detecting the focal position by detecting the image plane phase difference by the phase difference pixel disposed in the image sensor 1002 (image plane phase difference autofocus) can be used. Further, a method of detecting, as the focal position, a position at which an image exhibits the highest contrast (contrast autofocus) may be applied. The imaging control unit 1003 adjusts the position of the lens 1001 via the lens drive unit 1004 on the basis of the detected focal position to perform autofocusing. Note that the imaging control unit 1003 can include, for example, a DSP (Digital Signal Processor) on which firmware is mounted.

The lens drive unit 1004 drives the lens 1001 on the basis of the control of the imaging control unit 1003. This lens drive unit 1004 is capable of driving the lens 1001 by changing the position of the lens 1001 using a built-in motor.

The image processing unit 1005 processes the image signal generated by the image sensor 1002. For example, demosaicking for generating an image signal of an insufficient color among image signals corresponding to red, green, and blue for each pixel, noise reduction for removing noise from an image signal, encoding of an image signal, and the like correspond to this processing. The image processing unit 1005 can include, for example, a microcomputer on which firmware is mounted.

The operation input unit 1006 receives an operation input from a user of the camera 1000. As this operation input unit 1006, for example, a push button or a touch panel can be used. The operation input received by the operation input unit 1006 is transmitted to the imaging control unit 1003 and the image processing unit 1005. After that, the processing corresponding to the operation input, e.g., processing such as imaging a subject is started.

The frame memory 1007 is a memory for storing a frame that is an image signal for one screen. This frame memory 1007 is controlled by the image processing unit 1005, and maintains the frame during the image processing.

The display unit 1008 displays the image processed by the image processing unit 1005. As this display unit 1008, for example, a liquid crystal panel can be used.

The recording unit 1009 records the image processed by the image processing unit 1005. As this recording unit 1009, for example, a memory card or a hard disk can be used.

A camera to which the present disclosure can be applied has been described above. The present technology can be applied to the image sensor 1002 of the configurations described above. Specifically, the image sensor 1 described in FIG. 1 can be applied to the image sensor 1002. By applying the image sensor 1 to the image sensor 1002, it is possible to improve the dynamic range, and prevent the image quality of the image generated by the camera 1000 from being deteriorated. Note that the detection of the polarization information described in FIG. 4 can be performed in the image processing unit 1005. Note that the image processing unit 1005 is an example of the processing circuit described in the claims. The camera 1000 is an example of the imaging apparatus described in the claims.

Note that although a camera has been described as an example here, the technology according to the present disclosure may be applied to, for example, a monitoring apparatus. Further, the present disclosure can be applied to a semiconductor apparatus in the form of semiconductor module in addition to an electronic apparatus such as a camera. Specifically, the technology according to the present disclosure can be applied to an imaging module that is a semiconductor module in which the image sensor 1002 and the imaging control unit 1003 in FIG. 19 are enclosed in one package.

Finally, the description of the above-mentioned embodiments is an example of the present disclosure, and the present disclosure is not limited to the above-mentioned embodiments. Therefore, it goes without saying that various modifications can be made depending on the design and the like without departing from the technical idea according to the present disclosure even in the case of an embodiment other than the above-mentioned embodiments.

Further, the drawings in the above-mentioned embodiments are schematic, and the ratio of the dimensions of the respective units and the like do not necessarily coincide with real ones. Further, it goes without saying that the drawings have different dimensional relationships and different ratios of dimensions with respect to the same portion.

Further, the processing procedure described in the above-mentioned embodiments may be regarded as a method having the series of procedures, or may be regarded as a program for causing a computer to execute the series of procedures or a recording medium storing the program. As this recording medium, for example, a CD (Compact Disc), a DVD (Digital Versatile Disc), or a memory card can be used.

Note that the present technology may also take the following configurations.

(1) An image sensor, including:

a high-sensitivity pixel group including a plurality of high-sensitivity pixels; and

a low-sensitivity pixel group including a plurality of low-sensitivity pixels, in which

a polarization unit that causes incident light in a predetermined polarization direction to be transmitted therethrough is disposed in part of pixels of at least the high-sensitivity pixel group, of the high-sensitivity pixel group and the low-sensitivity pixel group.

(2) The image sensor according to (1) above, in which

the high-sensitivity pixel is configured to have a size different from that of the low-sensitivity pixel.

(3) The image sensor according to (1) or (2) above, in which

a plurality of the polarization units includes the polarization units having transmission axes in different directions when causing the incident light to be transmitted therethrough.

(4) The image sensor according to (3) above, in which

the plurality of polarization units includes the polarization units configured to have the transmission axes in three or more directions.

(5) The image sensor according to (3) above, in which

the plurality of polarization units includes the polarization units configured to have the transmission axes in two directions that are not perpendicular to each other.

(6) The image sensor according to (1) or (2) above, in which

a plurality of the polarization units has the transmission axes directed in the same direction.

(7) The image sensor according to (6) above, in which

the plurality of polarization units is configured to have the transmission axis in a direction perpendicular to a polarization direction of the incident light from a specific subject.

(8) The image sensor according to any one of (1) to (7) above, in which

the high-sensitivity pixel in which the polarization unit is disposed is configured to have a sensitivity higher than that of the low-sensitivity pixel.

(9) The image sensor according to any one of (1) to (8) above, in which

the polarization unit includes a wire grid including a plurality of strip conductors arranged at a predetermined pitch.

(10) The image sensor according to (9) above, in which

a plurality of the polarization units includes the polarization units configured to have different transmittances.

(11) The image sensor according to (10) above, in which

the polarization units are configured to have different transmittances by changing widths of the strip conductors.

(12) The image sensor according to (10) above, in which

the polarization units are configured to have different transmittances by changing intervals between the strip conductors.

(13) The image sensor according to (10) above, in which

the polarization unit disposed in the low-sensitivity pixel is configured to have a transmittance different from that of the polarization unit disposed in the high-sensitivity pixel.

(14) The image sensor according to (13) above, in which

the polarization unit disposed in the low-sensitivity pixel is configured to have a transmittance lower than that of the polarization unit disposed in the high-sensitivity pixel.

(15) The image sensor according to (10) above, in which

a plurality of pixel units includes pixels of the high-sensitivity pixel group and pixels of the low-sensitivity pixel group, the polarization unit being disposed in part of pixels of at least the high-sensitivity pixel group, of the pixels of the high-sensitivity pixel group and the pixels of the low-sensitivity pixel group, the plurality of pixel units including a plurality of the polarization units configured to have transmittances different from each other between the plurality of pixel units.

(16) An imaging apparatus, including:

a high-sensitivity pixel group including a plurality of high-sensitivity pixels;

a low-sensitivity pixel group including a plurality of low-sensitivity pixels; and

a processing circuit that processes an image signal generated by the pixel, in which

a polarization unit that causes incident light in a predetermined polarization direction to be transmitted therethrough is disposed in part of pixels of at least the high-sensitivity pixel group, of the high-sensitivity pixel group and the low-sensitivity pixel group.

### REFERENCE SIGNS LIST

1 image sensor
10 pixel array unit
30 column signal processing unit
100 high-sensitivity pixel group
101 to 104, 201 to 204 pixel
175 color filter
200 low-sensitivity pixel group
301 strip conductor
310, 320, 330, 350, 360, 370 polarization unit
501, 502, 511 to 514 pixel unit
1000 camera
1002 image sensor
1005 image processing unit

1. An image sensor, comprising:
a high-sensitivity pixel group including a plurality of high-sensitivity pixels; and
a low-sensitivity pixel group including a plurality of low-sensitivity pixels, wherein
a polarization unit that causes incident light in a predetermined polarization direction to be transmitted therethrough is disposed in part of pixels of at least the high-sensitivity pixel group, of the high-sensitivity pixel group and the low-sensitivity pixel group.

2. The image sensor according to claim 1, wherein
the high-sensitivity pixel is configured to have a size different from that of the low-sensitivity pixel.

3. The image sensor according to claim 1, wherein
a plurality of the polarization units includes the polarization units having transmission axes in different directions when causing the incident light to be transmitted therethrough.

4. The image sensor according to claim 3, wherein
the plurality of polarization units includes the polarization units configured to have the transmission axes in three or more directions.

5. The image sensor according to claim 3, wherein
the plurality of polarization units includes the polarization units configured to have the transmission axes in two directions that are not perpendicular to each other.

6. The image sensor according to claim 1, wherein
a plurality of the polarization units has the transmission axes directed in the same direction.

7. The image sensor according to claim 6, wherein
the plurality of polarization units is configured to have the transmission axis in a direction perpendicular to a polarization direction of the incident light from a specific subject.

8. The image sensor according to claim 1, wherein
the high-sensitivity pixel in which the polarization unit is disposed is configured to have a sensitivity higher than that of the low-sensitivity pixel.

9. The image sensor according to claim 1, wherein
the polarization unit includes a wire grid including a plurality of strip conductors arranged at a predetermined pitch.

10. The image sensor according to claim 9, wherein
a plurality of the polarization units includes the polarization units configured to have different transmittances.

11. The image sensor according to claim 10, wherein
the polarization units are configured to have different transmittances by changing widths of the strip conductors.

12. The image sensor according to claim 10, wherein
the polarization units are configured to have different transmittances by changing intervals between the strip conductors.

13. The image sensor according to claim 10, wherein
the polarization unit disposed in the low-sensitivity pixel is configured to have a transmittance different from that of the polarization unit disposed in the high-sensitivity pixel.

14. The image sensor according to claim 13, wherein
the polarization unit disposed in the low-sensitivity pixel is configured to have a transmittance lower than that of the polarization unit disposed in the high-sensitivity pixel.

15. The image sensor according to claim 10, wherein
a plurality of pixel units includes pixels of the high-sensitivity pixel group and pixels of the low-sensitivity pixel group, the polarization unit being disposed in part of pixels of at least the high-sensitivity pixel group, of the pixels of the high-sensitivity pixel group and the pixels of the low-sensitivity pixel group, the plurality of pixel units including a plurality of the polarization units configured to have transmittances different from each other between the plurality of pixel units.

16. An imaging apparatus, comprising:
a high-sensitivity pixel group including a plurality of high-sensitivity pixels;
a low-sensitivity pixel group including a plurality of low-sensitivity pixels; and
a processing circuit that processes an image signal generated by the pixel, wherein
a polarization unit that causes incident light in a predetermined polarization direction to be transmitted therethrough is disposed in part of pixels of at least the high-sensitivity pixel group, of the high-sensitivity pixel group and the low-sensitivity pixel group.
